(19) United States
(12) Patent Application Publication
(10) Pub. No.: US 2005/0196548 A1
(43) Pub. Date: Sep. 8, 2005

(54) Component protected against corrosion and method for the production thereof and device for carrying out the method

(75) Inventors: Klaus Goedicke, Dresden (DE); Fred Fietzke, Haenichen (DE); Steffen Straach, Dresden (DE); Volker Kirchhoff, Dresden (DE); Klaus-Dieter Hofmann, Goerlitz (DE); Frank Hollstein, Hirschfelde (DE)

Correspondence Address: GREENBLUM & BERNSTEIN, P.L.C., 1950 ROLAND CLARKE PLACE, RESTON, VA, 20191, US

(73) Assignee: Fraunhofer Gesellschaft Zur Foerderung Der Angewandten Forschung E.V., Muenchen (DE)

(21) Appl. No.: 11/064,964

(22) Filed: Feb. 25, 2005

Related U.S. Application Data
(63) Continuation-in-part of application No. PCT/EP03/09504, filed on Aug. 28, 2003.

(30) Foreign Application Priority Data
Aug. 30, 2002 (DE) 102 40 160.8

(51) Int. Cl. H05H 1/24; H01L 21/302; C23C 16/00

(52) U.S. Cl. 427/569; 118/723 VE

(57) ABSTRACT

Component having corrosion protection and including a base body made of one of a steel material and a light metal material. A corrosion-inhibiting surface layer that is a dense, fine-grained, largely pore-free structure formed by plasma-based vapor deposition. The surface layer having an average thickness of between 1 μm and 50 μm and being at least one layer of at least one of aluminum, an aluminum alloy, and an aluminum compound. This Abstract is not intended to define the invention disclosed in the specification, nor intended to limit the scope of the invention in any way.

### CROSS-REFERENCE TO RELATED APPLICATIONS

The present application is a continuation-in-part of International Patent Application No. PCT/EP2003/009504 filed Aug. 28, 2003, and claims priority of German Patent Application No. 102 40 160.8 filed Aug. 30, 2002. Moreover, the disclosure of International Patent Application No. PCT/EP2003/009504 is expressly incorporated by reference herein in its entirety.

### BACKGROUND OF THE INVENTION

1. Field of the Invention

The invention relates to a component protected against corrosion and comprising a base body and a corrosion-inhibiting surface layer, and to a method for the production thereof as well as a device for carrying out the method. Such components are often embodied as fastener elements such as rivets, bolts or screws. They are preferably used in the automotive industry, the aerospace industries, as well as in mechanical engineering and process plant engineering.

2. Discussion of Background Information

Numerous components are known which comprise a base body and a corrosion-inhibiting surface layer, whereby this surface layer is of a metallic, ceramic or organic nature. Chemical deposition and electrodeposition, above all electroplating deposition methods, are used to apply the surface layer to the base body. Examples of these are copper-plating, nickel-plating, chromium-plating and cadmium-plating. Layers of zinc and alloys thereof are applied by means of hot-dip coating. If the corrosion-inhibiting surface layer is of an organic nature, it is normally applied by spraying or dipping with subsequent hardening or crosslinking. Metallic/ceramic mixed layers, e.g., of a ceramic substrate with lamellar metallic components finely distributed therein, are also used (DELTA-Tone, DACROMET, U.S. Pat. No. 4,391,855, and U.S. 5,131,948).

All of the components with corrosion-inhibiting surface coating have in common that to produce them, surface coating methods are necessary which are more or less environmentally harmful. With increasing demands on the environmental compatibility of production methods, the cost of disposing of waste water, waste products or solvents is also rising. In addition, there are also great misgivings about the toxic effects or physiological risks of some of the materials of the surface layer themselves, e.g., in the case of cadmium, nickel and chromium.

In principle, components that have a corrosion-inhibiting surface layer can be produced by vacuum coating methods in a closed vacuum chamber without the disadvantages of environmental pollution. Vacuum coating methods also offer greater freedom with respect to the selection of materials. For example, surface layers of this type can be made from aluminum. However, so far such surface layers have not proven to provide sufficient corrosion protection unless further expensive additional coatings and/or aftertreatnent steps are carried out. An adequate corrosion protection effect of physically deposited surface layers with a thickness of a few to approx. 20 micrometers has hitherto been reported only if the methods for their production are designed to be ion-based or plasma-based. Aluminum and aluminum/magnesium layers were thus deposited by magnetron sputtering with so-called “unbalanced” magnetron sources (R. I. Bates, R. D. Arnell: Microstructure of novel corrosion-resistant coatings for steel components by unbalanced magnetron sputtering. Surf. Coat. Technol. 89 (1997), 204-212), or depositing a titanium layer on level steel plates through plasma-activated electron beam high-rate vapor deposition (C. Metzner, B. Scheffel, K. Goedicke: Plasma-activated electron beam deposition. Surf. Coat. Technol. 86-87 (1996), 769-775). The first method is too expensive because the deposition rate during sputtering is too low; the second method has not hitherto been usable for substrates with a three-dimensional shape.

The so-called McDonnell-Douglas method and the embodiment thereof that has become generally known as the IVD method (ion vapor deposition) known since 1975 from U.S. Pat. No. 3,750,623; U.S. Pat. No. 3,926,147 and U.S. Pat. No. 4,116,161, have hitherto been the only ion-based PVD methods (PVD=physical vapor deposition) which have achieved a certain widespread application in the aerospace industry. The IVD method is a PVD method for applying a corrosion-inhibiting surface layer onto base bodies by means of a vaporization method in which they are moved in rotating net-like or lattice-like baskets. It thereby uses a glow discharge in order to activate the condensation process through ion bombardment and to achieve a denser layer structure. With the McDonnell-Douglas method, as with the IVD method, corrosion-inhibiting coatings form, the corrosion protection effect of which, however, is insufficient without aftertreatment. An expensive aftertreatment through mechanical glass bead beams, a densification of the structure called “peening”, usually followed by a chromating or coating treatment is therefore necessary in order to achieve corrosion protection effects that meet the MIL-C-83488 C standard. It is still a drawback with a coating according to the McDonnell-Douglas method that the vapor generation takes place outside the lattice-like basket for accommodating the base bodies. An appreciable part of the vapor, approx. 30-50%, is thus lost for the actual coating of the base body and at the same time is responsible for the formation of particles and so-called flakes that lead to coating defects. Overall, the two specified PVD methods are so cost-intensive that it is impossible to use them in general mechanical engineering and auto manufacturing.

### SUMMARY OF THE INVENTION

The invention therefore creates a component comprising a base body and a corrosion-inhibiting surface layer and provides for a method for the production thereof as well as a device for carrying out the method which are free of the defects of the prior art. In particular, manufacturing costs are to be greatly reduced and an adequate corrosion resistance effect of the surface layer achieved without the structure of the applied layer having to be subsequently densified by mechanical means.

The invention also provides for a component having the features described herein. The method for producing the components according to the invention is set forth herein. A device for carrying out the method according to the invention is also described as are advantageous embodiments of this device.

The crux of the invention lies in applying a layer of aluminum or an aluminum alloy or aluminum compound of sufficient thickness and with such a layer structure to the base body as can only be achieved through direct action of a very dense plasma of relatively low ion energy during the layer formation. This dense layer structure already present immediately after the deposition renders an additional mechanical densification of the layer superfluous. If the base bodies are thereby randomly distributed and frequently changed in their position relative to the vapor sources, and if the special plasma becomes active during the condensation process directly and without electrically shielding lattices or nets between the plasma source and the base bodies during the layer formation, a uniform coating of high quality can be achieved even with base bodies with a complicated shape. A layer of this type is characterized by a dense, fine-grained, largely pore-free structure. The combination of the chemical/physical material properties and the layer structure of the surface layer which is formed on the surface of the base bodies in the course of the plasma-activated layer formation process, is the key to the high corrosion protection effect of the layer. According to the invention, the average thickness of the surface layer is between 1 μm and 50 m, whereby a layer thickness of between 10 μm and 25 μm already shows excellent corrosion protection effects. The stated lower limit of the layer thickness is suitable only for extremely low surface roughness of the base bodies and limited corrosion resistance. For the highest demands, in particular if, in addition to corrosion protection properties, a decorative appearance is also required and/or preset tribological demands are made on the component, the component according to the invention additionally comprises a layer of chromate or phosphate and/or a layer of an organic material. These layers are applied to the surface layer of aluminum or an aluminum alloy or aluminum compound in a manner known per se. If the component contains a surface layer of an aluminum alloy, according to the invention, an aluminum-magnesium alloy with a magnesium content of between 1% and 10% by weight, preferably between 3% and 5%, or an aluminum-zinc alloy with a zinc content of between 1% and 10% by weight, preferably between 2% and 5% are suitable, in particular. According to the invention, the surface layer can also be deposited with the action of a reactive gas and then contain aluminum compounds such as aluminum oxide, aluminum nitrate or aluminum carbide.

The method for producing the components according to the invention is carried out in a vacuum coating plant. This contains a drum or revolving basket that can be rotated about a horizontal axis. Vapor sources and plasma sources are located in the interior of the rotating basket. A plurality of base bodies are fixed essentially on the inner wall of the rotating basket for the purpose of applying the aluminum layer or the alloy or connecting layer and guided once or several times through a vapor cloud generated by metal vaporizers. Then an intermixing is carried out with a change of the position and orientation of the base bodies relative to the vapor sources, and the base bodies thus fixed in a changed position and direction are again guided through the vapor cloud once or several times. The alternation of intermixing and fixing the base bodies and their coating is continued until the base bodies are provided with a surface layer of the stated average thickness on all sides and without defects. The method can be designed as a continuous-flow coating process for treating bulk goods. It is crucial for the production method that the vaporizers are arranged in the interior of the rotating basket and thus cause the layer formation directly, i.e., without nets, lattices or screen structures interposed, and that the coating takes place with plasma activation. The layer formation process takes place in the plasma of a hollow-cathode arc discharge. Ion energies of several to several tens of electron volts and a charge carrier density in the range of over 10¹⁰/cm³, typically over 10¹¹/cm³, are characteristic for plasmas of this type. It is also important for the effectiveness of the plasma, that the plasma sources are arranged in the interior of the rotating basket and no potential-determining screens or nets are located between the hollow-cathode plasma sources and the base bodies to be coated. The surface layer applied under these conditions has a dense, fine-grained, pore-free structure which provides the corrosion protection of the component.

It is expedient to accomplish the fixing of the base bodies during the transport through the vapor and plasma zone through centrifugal force and to ensure the necessary minimum rotational speed of the rotating basket therefor.

If the base bodies of the components are composed of a ferromagnetic steel material, a magnetic fixing of the base bodies can also be expedient. To this end, an arrangement of permanent magnets or an electromagnet with a plurality of poles, the field lines of which penetrate the wall of the rotating basket and effect the magnetic fixing of the base bodies, is located, e.g., in the upper area of the rotating basket, but outside and stationary. The intermixing of the base bodies with a change of direction and position then takes place when the base bodies, moved with the rotating basket, leave the area penetrated by the magnetic field and are subject to the effect of gravity.

In another embodiment of the method, the intermixing with a change of the direction and position of the base bodies takes place with the aid of a mechanically operating scraper that separates the base bodies from the wall of the rotating basket after they have passed through the vapor zone. A motor-driven rotating brush is also particularly suitable for accomplishing a plurality of direction and position changes for the base bodies.

In another embodiment of the method, the rotational speed of the rotating basket is changed frequently, preferably periodically, such that the rotational speed is at times higher than the rotational speed at which the base bodies are fixed by centrifugal force, and at times lower than this characteristic speed, whereby they are intermixed under the action of gravity and changed with respect to their position and location before they are fixed again by centrifugal force.

In a further embodiment of the method with ferromagnetic base bodies and fixing the base bodies through centrifugal force, the intermixing of the base bodies including the change of direction and position takes place through a device that contains a rotating roller with inner magnetic poles that likewise rotate. A direct mechanical contact between the wall of the rotating basket and the scraper device can thus be avoided and a particularly gentle mechanical treatment of the base bodies can be achieved.

It is stressed that the methods for the random intermixing of the base bodies described here are only by way of example and can be replaced by other equivalent steps or devices.

It is expedient to use as an evaporator one or more so-called boat evaporators heated by direct current passage, in which the evaporation material for the surface layer is fed in wire form. Such boat evaporators are most frequently made of titanium boride. Arrangements of many boat evaporators of the same type arranged next to one another in a parallel manner are suitable for carrying out the method in coating plants with greater longitudinal extension of the rotating basket.

Another embodiment of the production method uses one or preferably more electron beam evaporators to generate the aluminum vapor or the vapor of the aluminum alloy. So-called transverse evaporators are used in coating plants of smaller output. In coating plants of large output, electron beam evaporators are used according to the invention which have a preferably ceramic evaporator crucible extended parallel to the axis of the rotating basket and a separate generating, focusing and deflecting unit for the electron beam in the form of a so-called axial electron gun.

Another expedient embodiment of the method according to the invention further provides that the base bodies are exposed to the effect of a dense plasma to activate their surface before the application of the surface layer. Such a plasma pretreatment known per se causes a desorption of foreign atoms, the removal of oxide contaminations and an energy activation of the surface, and thus ensures good adhesion and a uniform growth of the corrosion-inhibiting surface layer on the base bodies. A preferred embodiment of the method includes a pretreatment and activation of the surface of the base bodies using the dense plasma of one or more hollow-cathode arc discharges, thus the same plasma sources that are also used for the plasma-activated deposition of the surface layer. It is expedient for this to preset a defined negative potential of the rotating basket with the base bodies with respect to the plasma potential in order to adjust the energy of the ions during the plasma pretreatment in a suitable manner.

The invention also provides for a component having corrosion protection, wherein the component comprises a base body comprising one of a steel material and a light metal material and a corrosion-inhibiting surface layer comprising a dense, fine-grained, largely pore-free structure formed by plasma-based vapor deposition. The surface layer has an average thickness of between 1 μm and 50 μm and comprises at least one layer of at least one of aluminum, an aluminum alloy, and an aluminum compound.

The component may be a fastener. The average thickness can be between 10 μm and 25 μm. The surface layer may further comprise a layer of one of chromate and phosphate applied on the at least on layer. The surface layer may further comprise a layer of an organic material arranged on the at least one layer. The at least one layer may comprise the aluminum alloy, and the aluminum alloy is an aluminum-magnesium alloy with a magnesium content of between 1% and 10% by weight. The at least one layer may comprise the aluminum alloy, and the aluminum alloy is an aluminum-zinc alloy with a zinc content of between 1% and 10% by weight.

The invention also provides for a method of making the component described above, wherein the method comprises positioning the base body along with other base bodies in a vacuum coating arrangement so that the base body and the other base bodies are arranged essentially on an inner wall of a drum rotating about a horizontal axis, intermixing the base body and the other base bodies several times during a coating time, whereby positions and orientations of the base body and the other base bodies change, arranging evaporator sources within the drum, and coating the base body and the other base bodies with a plasma utilizing a hollow-cathode arc discharge that burns in an interior of the drum during the coating.

The method may further comprise subjecting the base body and the other base bodies to a centrifugal force so as to fix the base body and the other base bodies in the vacuum coating arrangement.

The method may further comprise subjecting the base body and the other base bodies to a magnetic force so as to fix the base body and the other base bodies in the vacuum coating arrangement.

The intermixing may comprise mechanically scraping the base body and the other base bodies from a drum wall. The intermixing may comprise magnetically scraping of the base body and the other base bodies from a drum wall. The intermixing may comprise intermittently reducing a rotational speed of the drum below a value necessary for fixing the base body and the other base bodies on the inner wall by centrifugal force.

The method may further comprise feeding, in wire form, a material forming the at least one layer.

The method may further comprise evaporating the material with the evaporator sources, wherein the evaporator sources comprise one or more boat evaporators heated by direct current.

The method may further comprise evaporating a material forming the at least one layer with the evaporator sources, wherein the evaporator sources comprise one or more boat evaporators heated by direct current.

The method may further comprise evaporating a material forming the at least one layer with the evaporator sources, wherein the evaporator sources comprise one or more electron beam evaporators having crucibles in which the material is located.

The method may further comprise, before the coating, preteating and activating a surface of the base body and of the other base bodies by exposing the surface to a dense plasma.

The method may further comprise, before the coating, preteating and activating a surface of the base body and of the other base bodies by exposing the surface to a hollow-cathode plasma.

The invention also provides for a vacuum coating arrangement for coating components with a plasma-activated coating, wherein the arrangement comprises a receiver that can be evacuated and at least one vapor source and at least one plasma source arranged in an interior of a rotating basket that can be rotated about a longitudinal axis, wherein the rotating basket comprises a wall to which the components can be fixed during coating.

The at least one vapor source may be an electron beam evaporator. The at least one vapor source may be a boat evaporator. The at least one plasma source may comprise at least one hollow-cathode plasma source.

The invention also provides for a component having corrosion protection coating, wherein the component comprises a metal base body and a dense, fine-grained, largely pore-free plasma-based vapor deposition coating comprising one of aluminum, an aluminum alloy, and an aluminum compound, wherein the metal base body is coated with said coating and said coating comprises a surface layer having an average thickness of between 1 μm and 50 μm.

The invention also provides for a method of making the component described above, wherein the method comprises positioning the metal base body along with other base bodies in a vacuum coating arrangement so that the base body and the other base bodies are arranged essentially on an inner wall of a drum rotating about a horizontal axis, intermixing the base body and the other base bodies several times during a coating time, whereby positions and orientations of the base body and the other base bodies can change, arranging evaporator sources within the drum, and coating the base body and the other base bodies with a plasma utilizing a hollow-cathode arc discharge that burns in an interior of the drum during the coating.

### BRIEF DESCRIPTION OF THE DRAWINGS

The invention will be explained in more detail in the following text by using an exemplary embodiment and with reference to the drawings, wherein:

FIG. 1 shows a schematic, partly sectioned illustration of a substrate handling unit;

FIG. 2 shows a schematic, partially sectioned illustration of a coating unit; and

FIG. 3 shows an SEM picture of an aluminum layer on a component according to the invention.

### DETAILED DESCRIPTION OF THE INVENTION

A component according to the invention, and a method for the production thereof, as well as the device necessary for carrying it out, are explained in more detail below in an exemplary embodiment.

The component has, by way of example, the function of a pop rivet with a length of 6 mm and a shaft diameter of 4 mm as is used in large quantities as a fastener element for the permanent mechanical connection of machine, plant and automotive body parts in mechanical engineering and automobile manufacturing. The material for the base body is unalloyed high-carbon steel C35 (material no. 1.0501). According to the invention, this body is covered on all sides with an aluminum alloy layer having an average thickness of 25 μm. Inside the recess of the rivet shaft, the layer thickness is about 15 μm. This surface layer is composed of an aluminum-magnesium alloy AlMg3 with a magnesium content of approx. 3% by weight. Under light-microscope and electron-microscope examination, the grinding pattern of the surface layer shows a dense, fine-grained structure without pores and with a typical grain size of 1 μm. There is no poled layer growth, and thus no grain boundaries, that run through the entire layer. In the salt-spray fog test, no red rust formation was observed after 200 hours. A test of a large number of these components shows that they meet the demands of standard MIL-C-83488 C, which is widespread in aircraft construction.

The coating method for applying the surface layer of AlMg3 to the base body includes a PVD process that is carried out in a vacuum coating plant.

The main chamber of the coating plant has a volume of approx. 1 cubic meter and accommodates a water-cooled rotating basket with a diameter of 800 mm and a length of 700 mm. The rotating basket is supported on one side, in a horizontal manner, and driven by a motor; it typically rotates at 72 revolutions per minute. The circumferential surface of the rotating basket is closed. A fixed traverse is attached on the face side opposite the rotary drive, which traverse serves as a mounting plate for six boat evaporators arranged next to one another with a reciprocal spacing of 100 mm, each with a TiB₂ boat and a wire feeder and three hollow-cathode plasma sources. The boat evaporators are each heated by 800 A at 15 V. With the wire feed, an evaporation rate of 5 grams per minute and evaporator is established. The wire has the composition and quality AlMg3 F22. The hollow-cathode arc discharges burn respectively with an argon inlet of 80 sccm with 300 A at a burning voltage of 30-35 V between each hollow cathode, and two electrodes arranged symmetrically between the boat evaporators and switched as an anode. The coating plant works quasi-continuously without vacuum interruption. To this end, it is equipped with, respectively, one vacuum lock that can be evacuated separately for extracting and inserting 25 kg of the base bodies. The transfer of the base bodies from the intake lock into the rotating basket, or from the rotating basket into the outlet lock, takes place through, respectively, one valve and tubular guide devices under the effect of gravity. After a degreasing and washing process, the base bodies are poured into the intake lock of the coating plant in batches and in portions of 25 kg. After degassing, they are transferred to the rotating basket and pretreated there for 10 minutes in the dense hollow-cathode plasma. The rotating basket is located at a negative potential of 500 V. The subsequent process for plasma-activated vapor deposition takes 20 minutes. During the plasma pretreatment and coating, the base bodies are fixed by centrifugal force on the inner wall of the rotating basket and lie on top of one another in approximately three layers evenly randomly distributed. The periodic scraping of the base bodies before repeated centrifugal force fixation is carried out by rotating metal brushes. The rotating basket is braked and tilted to transfer the coated base bodies into the outlet lock. A pivoting plate is used to avoid a collision of the downward-falling components with the evaporators and plasma sources. A batch of approx. 25 kg of the coated components is released from the installation at intervals of 35 minutes respectively. The parts are checked and packed. The high productivity of the coating plant, and the avoidability of cost-intensive aftertreatments of the surface layer, result in low production costs for the components according to the invention.

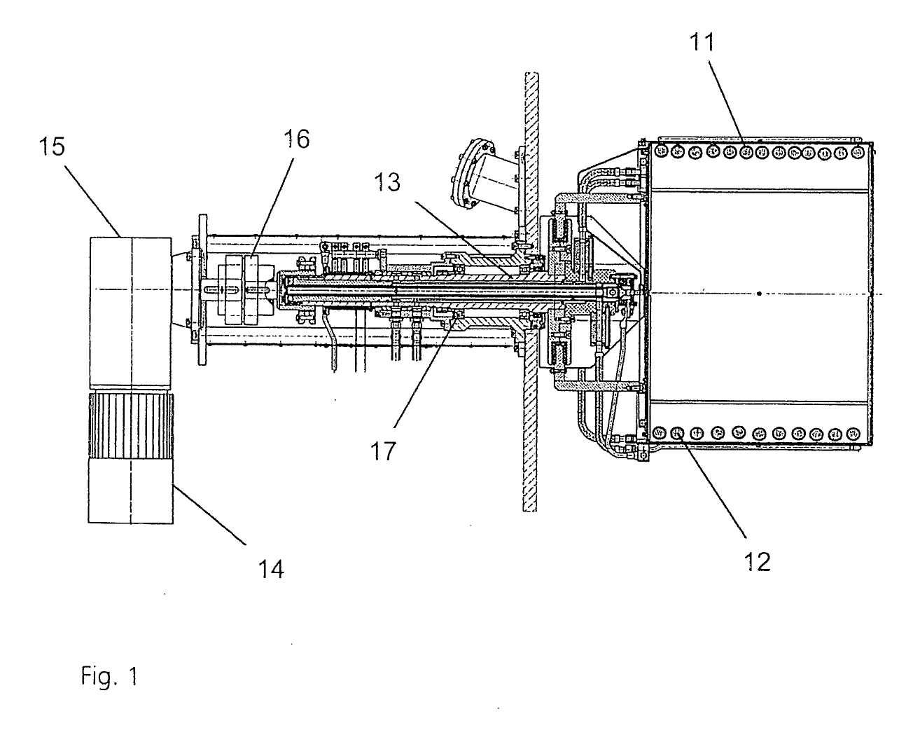

FIG. 1 shows one non-limiting substrate handling unit which can be used to practice the invention. The apparatus utilizes, among other things, a rotating drum 11, within which the base bodies 12 are arranged. As shown in FIG. 1, the base bodies 12 are arranged adjacent an inner wall of the rotating drum 11. The apparatus further includes a rotary vacuum feedthrough 13, a motor 14, a transmission 15, a slipping clutch 16 and a bearing 17.

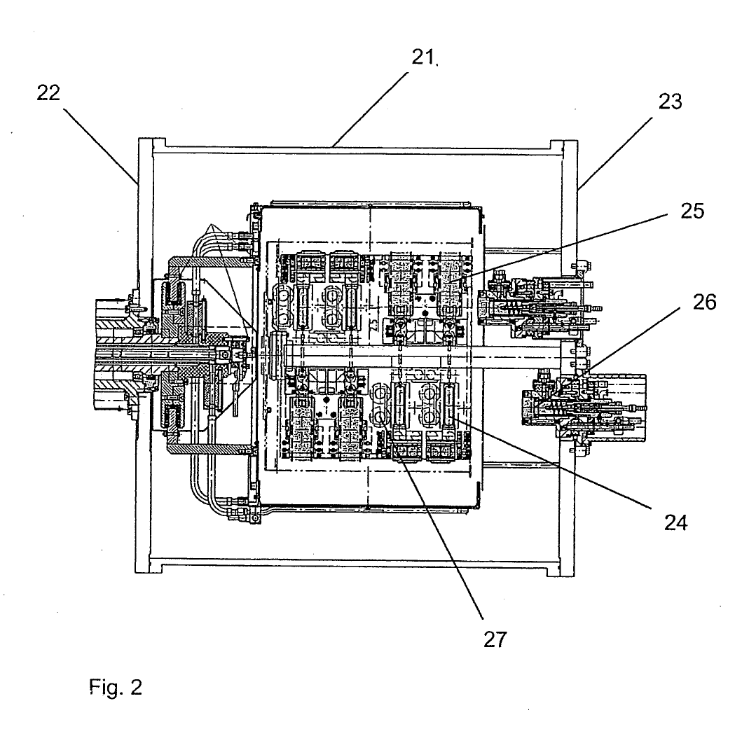

FIG. 2 shows one non-limiting coating unit which can be used to practice the invention. The unit utilizes, among other things, a receiver or vacuum chamber 21. A first flange 22, which is part of the substrate handling unit, is located on one side of the vacuum chamber 21 and a second flange 23, which is part of the coating unit, is arranged on another side of the vacuum chamber 21. The unit further includes evaporation boats or evaporator sources 24 which function as a vapor source. The arrangement also includes a storage reel 25 for aluminum wire, a hollow cathode 26 which functions as the plasma source and a booster anode 27 which functions to spread the plasma.

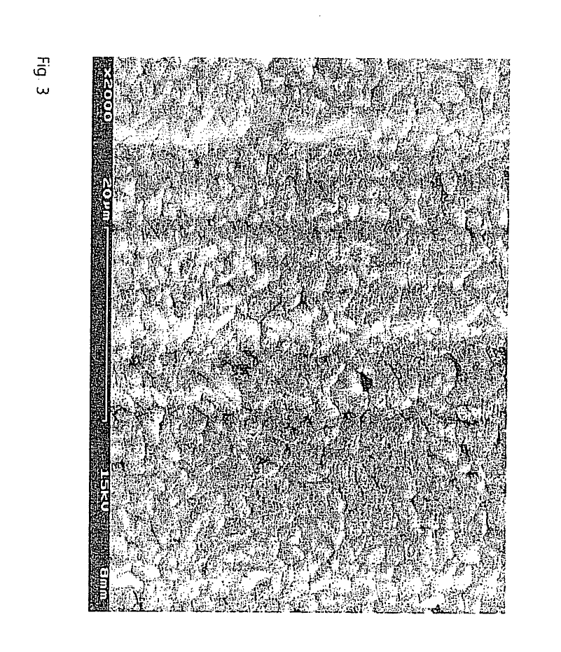

FIG. 3 shows an SEM picture of an aluminum layer on a component according to the invention.

1. A component having corrosion protection, the component comprising:
a base body comprising one of a steel material and a light metal material;
a corrosion-inhibiting surface layer comprising a dense, fine-grained, largely pore-free structure formed by plasma-based vapor deposition; and
said surface layer having an average thickness of between 1 μm and 50 μm and comprising at least one layer of at least one of aluminum, an aluminum alloy, and an aluminum compound.

2. The component of claim 1, wherein the component is a fastener.

3. The component of claim 1, wherein the average thickness is between 10 μm and 25 μm.

4. The component of claim 1, wherein said surface layer further comprises a layer of one of chromate and phosphate applied on the at least on layer.

5. The component of claim 1, wherein said surface layer further comprises a layer of an organic material arranged on the at least one layer.

6. The component of claim 1, wherein the at least one layer comprises the aluminum alloy, and the aluminum alloy is an aluminum-magnesium alloy with a magnesium content of between 1% and 10% by weight.

7. The component of clain 1, wherein the at least one layer comprises the aluminum alloy, and the aluminum alloy is an aluminum-zinc alloy with a zinc content of between 1% and 10% by weight.

8. A method of making the component of claim 1, the method comprising:
positioning the base body along with other base bodies in a vacuum coating arrangement so that the base body and the other base bodies are arranged essentially on an inner wall of a drum rotating about a horizontal axis;
intermixing the base body and the other base bodies several times during a coating time, whereby positions and orientations of the base body and the other base bodies change;
arranging evaporator sources within the drum; and
coating the base body and the other base bodies with a plasma utilizing a hollow-cathode arc discharge that burns in an interior of the drum during the coating.

9. The method of claim 8, further comprising subjecting the base body and the other base bodies to a centrifugal force so as to fix the base body and the other base bodies in the vacuum coating arrangement.

10. The method of claim 8, further comprising subjecting the base body and the other base bodies to a magnetic force so as to fix the base body and the other base bodies in the vacuum coating arrangement.

11. The method of claim 8, wherein the intermixing comprises mechanically scraping the base body and the other base bodies from a drum wall.

12. The method of claim 8, wherein the intermixing comprises magnetically scraping of the base body and the other base bodies from a drum wall.

13. The method of claim 8, wherein the intermixing comprises intermittently reducing a rotational speed of the drum below a value necessary for fixing the base body and the other base bodies on the inner wall by centrifugal force.

14. The method of claim 8, further comprising feeding, in wire form, a material forming the at least one layer.

15. The method of claim 14, further comprising evaporating the material with the evaporator sources, wherein the evaporator sources comprise one or more boat evaporators heated by direct current.

16. The method of claim 8, further comprising evaporating a material forming the at least one layer with the evaporator sources, wherein the evaporator sources comprise one or more boat evaporators heated by direct current.

17. The method of claim 8, further comprising evaporating a material forming the at least one layer with the evaporator sources, wherein the evaporator sources comprise one or more electron beam evaporators having crucibles in which the material is located.

18. The method of claim 8, further comprising, before the coating, preteating and activating a surface of the base body and of the other base bodies by exposing the surface to a dense plasma.

19. The method of claim 8, further comprising, before the coating, preteating and activating a surface of the base body and of the other base bodies by exposing the surface to a hollow-cathode plasma.

20. A vacuum coating arrangement for coating components with a plasma-activated coating, the arrangement comprising:
a receiver that can be evacuated; and
at least one vapor source and at least one plasma source arranged in an interior of a rotating basket that can be rotated about a longitudinal axis,
wherein the rotating basket comprises a wall to which the components can be fixed during coating.

21. The vacuum coating arrangement of claim 20, wherein the at least one vapor source is an electron beam evaporator.

22. The vacuum coating arrangement of claim 20, wherein the at least one vapor source is a boat evaporator.

23. The vacuum coating arrangement of claim 20, wherein the at least one plasma source comprises at least one hollow-cathode plasma source.

24. A component having corrosion protection coating, the component comprising:
a metal base body; and
a dense, fine-grained, largely pore-free plasma-based vapor deposition coating comprising one of aluminum, an aluminum alloy, and an aluminum compound,
wherein the metal base body is coated with said coating and said coating comprises a surface layer having an average thickness of between 1 μm and 50 μm.

25. A method of making the component of claim 24, the method comprising:
positioning the metal base body along with other base bodies in a vacuum coating arrangement so that the base body and the other base bodies are arranged essentially on an inner wall of a drum rotating about a horizontal axis;
intermixing the base body and the other base bodies several times during a coating time, whereby positions and orientations of the base body and the other base bodies can change;
arranging evaporator sources within the drum; and
coating the base body and the other base bodies with a plasma utilizing a hollow-cathode arc discharge that bums in an interior of the drum during the coating.
